(19) United States
(12) Patent Application Publication
(10) Pub. No.: US 2018/0012835 A1
(43) Pub. Date: Jan. 11, 2018

(54) SEMICONDUCTOR DEVICE AND METHOD FOR MANUFACTURING THE SAME

(71) Applicant: SK hynix Inc., Gyeonggi-do (KR)

(72) Inventor: Jong Hoon KIM, Gyeonggi-do (KR)

(21) Appl. No.: 15/464,603

(22) Filed: Mar. 21, 2017

(30) Foreign Application Priority Data
Jul. 11, 2016 (KR) 10-2016-0087512

(51) Int. Cl. H01L 23/528; H01L 23/522; H01L 21/768; H01L 23/532

(52) U.S. Cl. CPC H01L 23/528; H01L 23/5329; H01L 23/53238; H01L 23/5226; H01L 21/76804; H01L 21/76843; H01L 21/76829; H01L 21/76877

(57) ABSTRACT

A semiconductor device and a method for manufacturing the same are disclosed, which guarantee an overlay margin between a contact and a metal line. A method for manufacturing a semiconductor device includes: forming a stacked insulation film in which a first interlayer insulation film, an etch stop film, and a second interlayer insulation film are sequentially stacked, over a lower structure; forming a contact hole by etching the stacked insulation film; forming a contact by burying a conductive film in the first interlayer insulation film and the etch stop film within the contact hole; and forming a metal line coupled to a top surface of the contact.

### CROSS-REFERENCE TO RELATED APPLICATION

This application claims priority under 35 U.S.C. §119 to Korean Patent Application No. 10-2016-0087512, filed on Jul. 11, 2016, in the Korean Intellectual Property Office, the disclosure of which is incorporated herein by reference in its entirety.

### BACKGROUND OF THE INVENTION

Embodiments of the present disclosure relate to a semiconductor device and a method for manufacturing the same, and more particularly to a semiconductor device having an overlay margin between a contact and a metal line, and a method for manufacturing the same.

Generally, a semiconductor device includes a metal line for electrically interconnecting between devices or between lines. In addition, the semiconductor device further includes a contact for interconnecting between an upper metal line and a lower metal line.

The metal line is generally formed of aluminum (Al) and/or tungsten (W) having superior electrical conductivity. In recent times, many developers and companies are conducting intensive research into a method for using copper (Cu) having higher electrical conductivity and lower resistance than aluminum (Al) and tungsten (W) for solving a signal delay concern encountered in highly-integrated and high-speed operating elements, as the next-generation metal line material.

Since a dry etching method is not suitable for forming the metal line formed of copper (Cu), a new fabrication technology called a damascene process is needed to form the copper (Cu) line.

However, as the semiconductor device is highly integrated, a cell size is gradually reduced, the semiconductor device is gradually increased in height, and Critical Dimension (CD) is gradually reduced, resulting in reduction of an overlay margin between a contact and a metal line.

For example, the size of an upper part of the contact needs to be increased to prevent occurrence of a not-open state, such that an overlay margin between the contact and a contiguous metal line is greatly reduced.

### SUMMARY OF THE INVENTION

Various embodiments of the present disclosure are directed to a semiconductor device and a method for manufacturing the same that substantially obviate one or more problems due to limitations and disadvantages of the related art.

An embodiment of the present disclosure relates to a method for manufacturing a semiconductor device capable of guaranteeing an overlay margin between a contact and a metal line.

In accordance with an aspect of the present disclosure, a method for manufacturing a semiconductor device includes: forming a stacked insulation film in which a first interlayer insulation film, an etch stop film, and a second interlayer insulation film are sequentially stacked, over a lower structure; forming a contact hole by etching the stacked insulation film; forming a contact by burying a conductive film in the first interlayer insulation film and the etch stop film within the contact hole; and forming a metal line coupled to a top surface of the contact.

In accordance with another aspect of the present disclosure, a semiconductor device includes: a stacked insulation film in which a first interlayer insulation film, an etch stop film, and a second interlayer insulation film are sequentially stacked, over a lower structure; a contact having an upper part buried in the etch stop film and a lower part buried in the first interlayer insulation film; and a metal line formed to proceed in a first direction while simultaneously contacting a top surface of the contact, and formed to be buried in the second interlayer insulation film. The width of the lower part of the contact is gradually reduced in proportion to a depth within the first interlayer insulation film, and a width of the upper part of the contact is smaller than a width of a top surface of the lower part of the contact which is formed in the first interlayer insulation film.

It is to be understood that both the foregoing general description and the following detailed description of embodiments are exemplary and explanatory.

### BRIEF DESCRIPTION OF THE DRAWINGS

The above and other features and advantages of the present disclosure will become readily apparent by reference to the following detailed description when considered in conjunction with the accompanying drawings wherein:

FIGS. 1A and 1B are views illustrating a semiconductor device according to an embodiment of the present disclosure.

FIGS. 2A to 9B are cross-sectional views illustrating a method for manufacturing the semiconductor device according to an embodiment of the present disclosure.

FIGS. 10A and 10B are views illustrating contact holes formed in a line and in a zigzag pattern, respectively.

### DETAILED DESCRIPTION OF EMBODIMENTS

Reference will now be made in detail to certain embodiments of the present invention in conjunction with the accompanying drawings. The present disclosure, however, may be embodied in various different forms, and should not be construed as being limited to the illustrated embodiments herein. Rather, these embodiments are provided as examples so that this disclosure will be thorough and complete, and will fully convey the various aspects and features of the present invention to those skilled in the art.

Wherever possible, the same reference numbers will be used throughout the drawings to refer to the same or like parts. In the following description, a detailed description of related known configurations or functions incorporated herein may be omitted to avoid making the subject matter of the present invention less clear.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to more clearly illustrate the various elements of the embodiments. For example, in the drawings, the size of elements and the intervals between elements may be exaggerated compared to actual sizes and intervals for convenience of illustration.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

Spatially relative terms, such as “under,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in manufacturing, use or operation in addition to the orientation depicted in the figures. For example, if the device in the figures is turned over, elements described as “below” or “under” other elements or features would then be “above” the other elements or features. The device may be otherwise oriented (rotated 90 degrees or at other orientations) and the spatially relative descriptors used herein interpreted accordingly.

In the following description, numerous specific details are set forth in order to provide a thorough understanding of the present invention. The present invention may be practiced without some or all of these specific details. In other instances, well-known structures and/or processes have not been described in detail in order not to unnecessarily obscure the present invention.

It is also noted, that in some instances, as would be apparent to those skilled in the relevant art, an element (also referred to as a feature) described in connection with one embodiment may be used singly or in combination with other elements of another embodiment, unless specifically indicated otherwise.

Hereinafter, the various embodiments of the present invention will be described in detail with reference to the attached drawings.

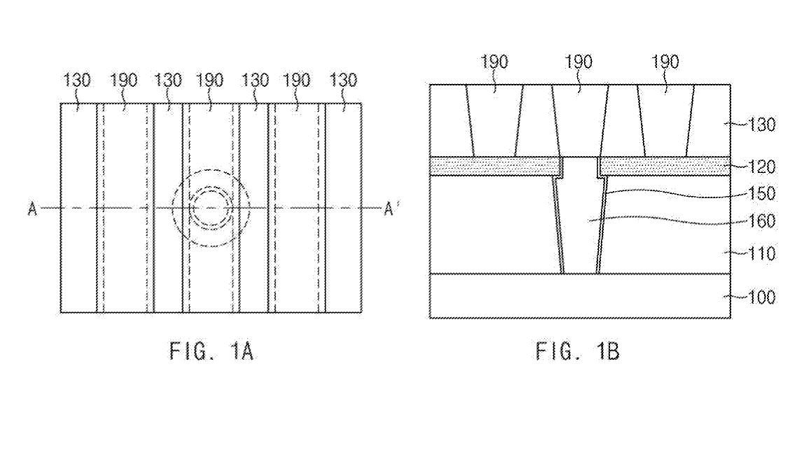

FIGS. 1A and 1B are views illustrating a semiconductor device according to an embodiment of the present disclosure. In more detail, FIG. 1A is a plan view illustrating the semiconductor device, and FIG. 1B is a cross-sectional view illustrating the semiconductor device taken along the line A-A′ of FIG. 1A.

Referring to FIGS. 1A and 1B, a first interlayer insulation film 110, an etch stop film 120, and a second interlayer insulation film 130 are sequentially stacked in the recited order over the lower structure 100. The lower structure 100 may include a specific structure such as a gate (not shown).

The first interlayer insulation film 110 and the second interlayer insulation film 130 may be formed of the same material, for example, an oxide film. The etch stop film 120 may be formed of a nitride film having an etch selection ratio different from those of the first interlayer insulation film 110 and the second interlayer insulation film 130.

A barrier metal film 150 and a contact 160 may be formed in the first interlayer insulation film 110 and the etch stop film 120 of the stacked insulation film.

The contact 160 may include two parts, an upper part formed within the etch stop film 120 and a lower part formed within the first interlayer insulation film 110. The lower part of the contact 160 may be tapered and may have a cross-section that is gradually reduced in width in proportion to a depth within the first interlayer insulation film 110. More specifically, as illustrated in FIG. 1B, the lower part of the contact 160 which is formed within the first interlayer insulation film 110 has its largest cross-section at a top surface thereof at the transition point between the etch stop film 120 and the first interlayer insulation film 110. The upper part of the contact 160 which is formed within the etch stop film 120 has a constant area cross-section with a width that is smaller than the width of the top surface of the lower part of the contact 160 that is formed in the first interlayer insulation film 110. Preferably, as illustrated in FIG. 1B, the width of the cross-section of the upper part of the contact 160 that is formed in the etch stop film 120 may be identical or substantially identical to the width of the bottom surface of the lower part of the contact 160. By forming the top surface of the contact 160 to have the same or substantially the same size as the bottom surface of the contact 160, a process margin can be guaranteed when a metal line 190 is formed over the contact 160.

In an embodiment, the barrier metal film 150 may include titanium (Ti), titanium nitride (TIN), or a stacked structure thereof. The contact 160 may include tungsten (W), however, any other suitable metal may be used. A plurality of parallel metal lines 190 are formed in the second interlayer insulation film 130 in a line shape (see FIG. 1A). As shown in FIG. 1B, the metal line 190 is contacting the top surface of the contact 160 (see FIG. 1B).

As illustrated in FIGS. 1A and 1B, a lateral surface of the metal line 190 is tapered in a manner that the width of the bottom surface of the metal line 190 is smaller than the width of the top surface of the metal line 190. The bottom surface of the metal line 190 may be identical or substantially identical in width to the upper part of the contact 160.

The metal line 190 may include any suitable metal such as aluminum (Al), tungsten (W) or copper (Cu). The metal line 190 may preferably include copper (Cu).

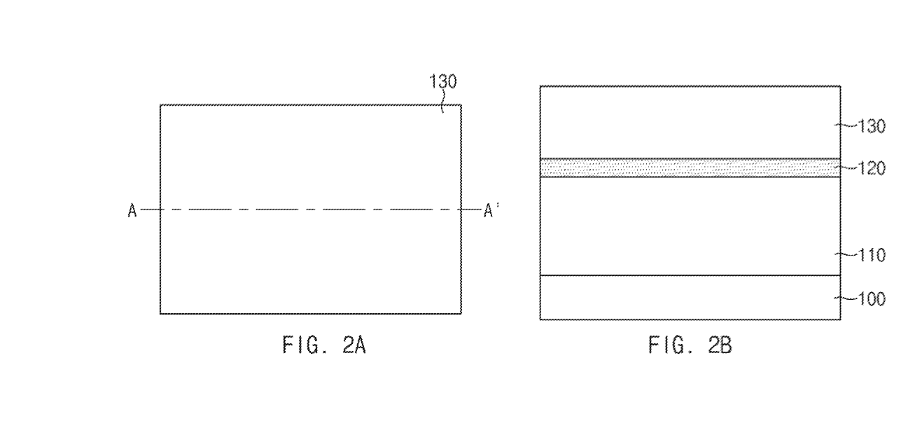

FIGS. 2A to 9B are cross-sectional views illustrating a method for manufacturing the semiconductor device according to an embodiment of the present disclosure. In each of FIGS. 2A to 9B, figures denoted with the letter “A” are plan views illustrating the semiconductor device, whereas figures denoted with the letter “B” are cross-sectional views illustrating the semiconductor device taken along a line A-A′ illustrated in a corresponding plan view figure.

Referring to FIGS. 2A and 2B, a first interlayer insulation film 110 may be formed over a lower structure 100. The lower structure 100 may include a specific structure such as a gate (not shown). The first interlayer insulation film 110 may be or include an oxide film. For example, the first interlayer insulation film 110 may be silicon dioxide.

Subsequently, the etch stop film 120 may be formed over the first interlayer insulation film 110. In this case, the etch stop film 120 may include a material (for example, a nitride film such as silicon nitride) having an etch selection ratio different from that of the first interlayer insulation film 110. The nitride film may be formed by any suitable method including for example a CVD method using silane and ammonia gas.

After formation of the etch stop film 120, the second interlayer insulation film 130 may be formed over the etch stop film 120. In this case, the second interlayer insulation film 130 may include the same material (e.g., an oxide film) as the first interlayer insulation film 110. The first and second interlayer insulation layers 110 and 130 may be formed using any suitable method such as for example exposing the wafer to a flow of oxygen gas inside a high temperature furnace.

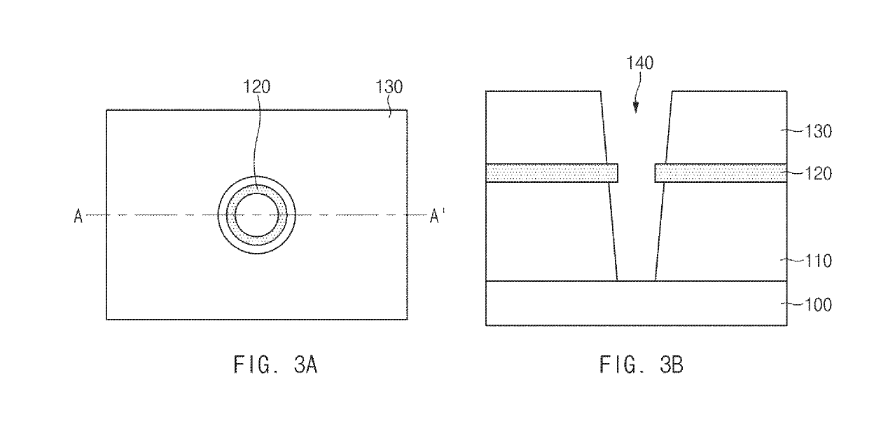

Referring to FIGS. 3A and 3B, after a contact mask (not shown) for defining a contact region is formed over the second interlayer insulation film 130, the second interlayer insulation film 130, the etch stop film 120, and the first interlayer insulation film 110 are etched using the contact mask as an etch mask, resulting in formation of a contact hole 140. The contact mask may be formed for example by employing a photoresist method.

When forming the contact hole 140, the etch stop film 120 is less etched than the interlayer insulation films (110, 130) using a difference in etch selection ratio between the etch stop film 120 and the interlayer insulation films (110, 130), such that some parts of the etch stop film 120 may protrude inward from the contact hole 140 as shown in FIGS. 3A and 3B. In other words, the width (or diameter) of the contact hole 140 is gradually reduced in proportion to the increasing depth of the contact hole 140, and some parts of the etch stop film 120 may protrude inward from the contact hole 140 at the part in which the etch stop film 120 is formed.

In this case, the width (diameter) of each hole formed by the protruded etch stop film 120 may be identical to the width (diameter) of the bottom surface of the contact hole 140.

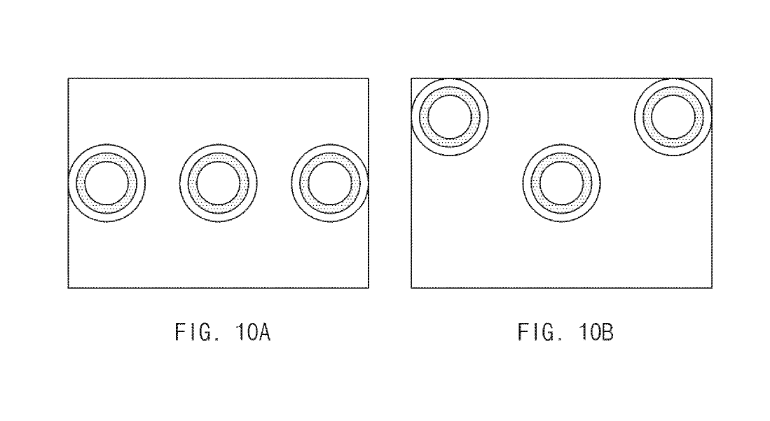

Although FIGS. 3A and 3B illustrate only one contact hole 140 for convenience of description, a plurality of contact holes may be closely arranged in a line pattern or in a zigzag pattern as shown in FIGS. 10A and 10B, respectively. In an embodiment, the contact holes may be contact holes to form drain contacts of a flash memory.

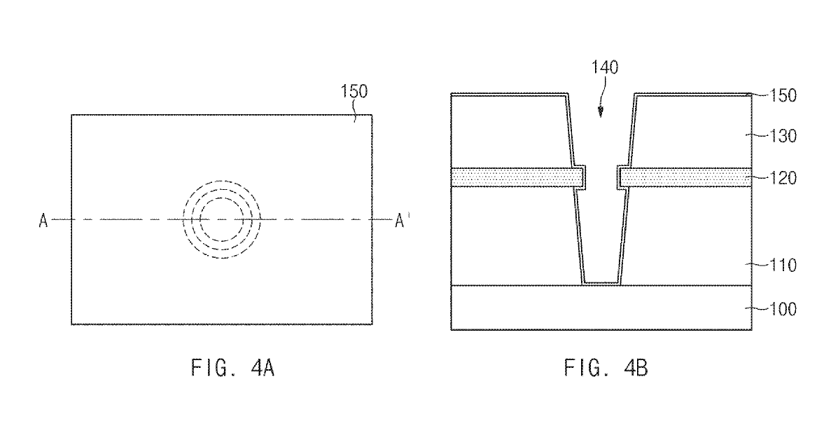

Referring to FIGS. 4A and 4B, a barrier metal film 150 may be formed not only at a sidewall of the contact hole 140 but also over the second interlayer insulation film 130. In this case, the barrier metal film 150 may be or include, for example, titanium (Ti), titanium nitride (TiN), or a stacked structure thereof.

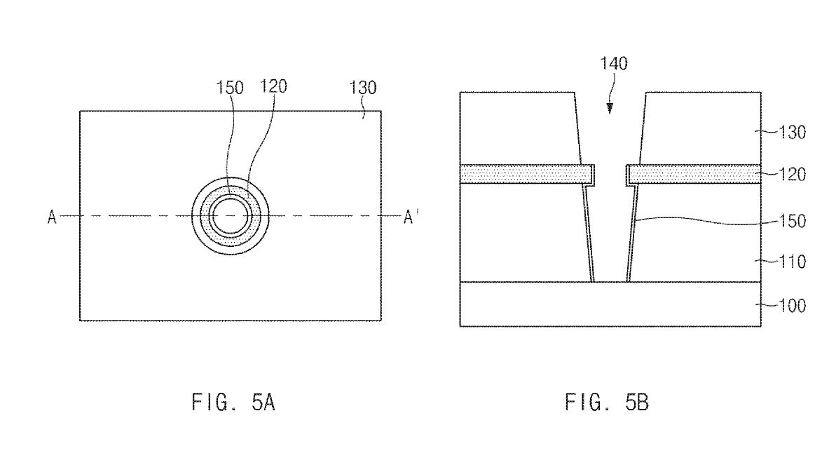

Referring to FIGS. 5A and 5B, the barrier metal film 150 is etched back, and the barrier metal film 150 formed at a sidewall of the second interlayer insulation film 130 and over the protruded etch stop film 120 may be selectively removed.

That is, the etch-back process is performed to the depth of the protruded etch stop film 120, such that the barrier metal film 150 may remain only at sidewalls of the first interlayer insulation film 110 and the etch stop film 120.

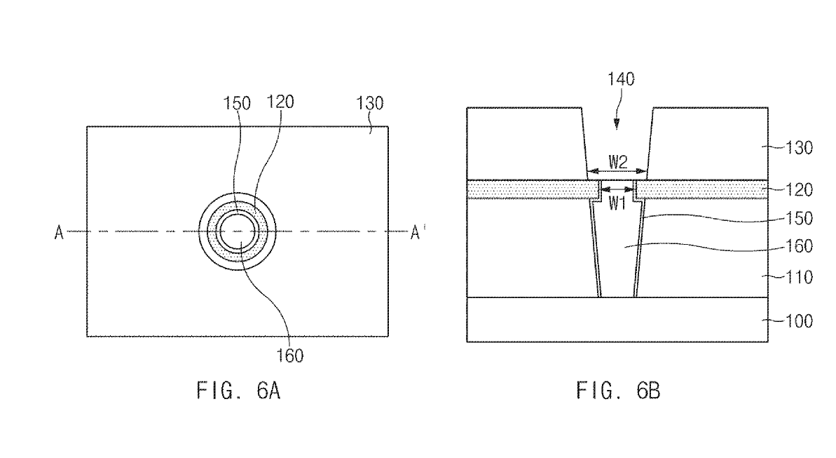

Referring to FIGS. 6A and 6B, a conductive film is formed over the barrier metal film 150 in a manner that the contact hole 140 is buried with the conductive film, then the conductive film is etched, to form the contact 160. The conductive film to be used for the contact 160 may be or include a metal, for example, tungsten (W).

For example, after formation of a conductive film to fill the contact hole 140, the conductive film may be planarized, using for example, a Chemical Mechanical Polishing process (CMP). In the planarization process, conductive film contained in the region not contacting the barrier metal film 150 is selectively removed, so that a contact may be formed only in the region contacting the barrier metal film 150 within the contact hole 140. In more detail, the contact 160 may be formed only in the region in which the first interlayer insulation film 110 and the etch stop film 120 are formed.

In this example, since the width W1 of the top surface of the contact 160 is determined by the protruded etch stop film 120, the width W1 of the top surface of the contact 160 is smaller than the width W2 obtained when the etch stop film 120 is not used.

In the planarization process (e.g., the CMP process), the second interlayer insulation film 130 may also be etched to a predetermined thickness.

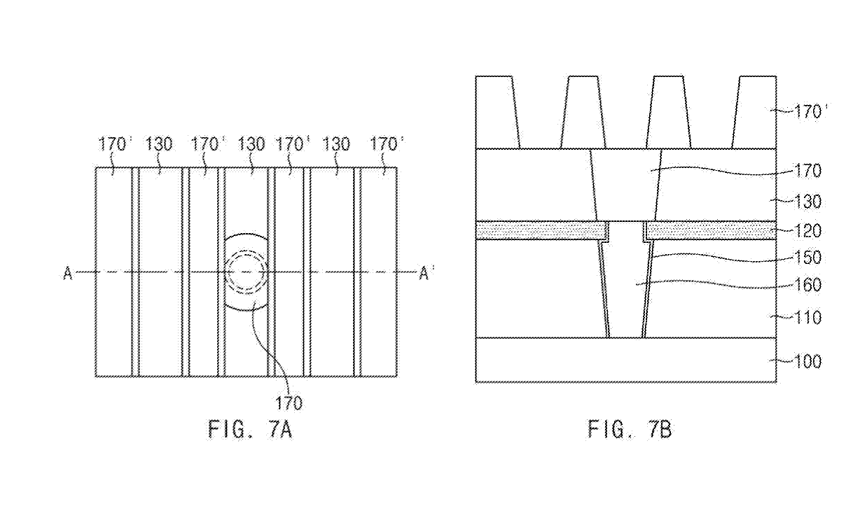

Referring to FIGS. 7A and 7B, after a photoresist film 170 is formed over the second interlayer insulation film 130 in a manner that the contact hole 140 is buried with the photoresist film 170, an exposure and development process is performed on the photoresist film 170, such that a photoresist pattern 170′ defining the metal line (e.g., a bit line) is formed.

As illustrated in FIG. 7B, the lower part of the photoresist pattern 170′ is larger in width than the upper part of the photoresist pattern 170′, so that a lateral surface of the photoresist pattern 170′ is formed as a tilted-line-shaped pattern. That is, the photoresist pattern 170′ may be formed in a manner that the upper part of a metal line region defined by the photoresist pattern 170′ is larger in width than the bottom surface of the metal line region.

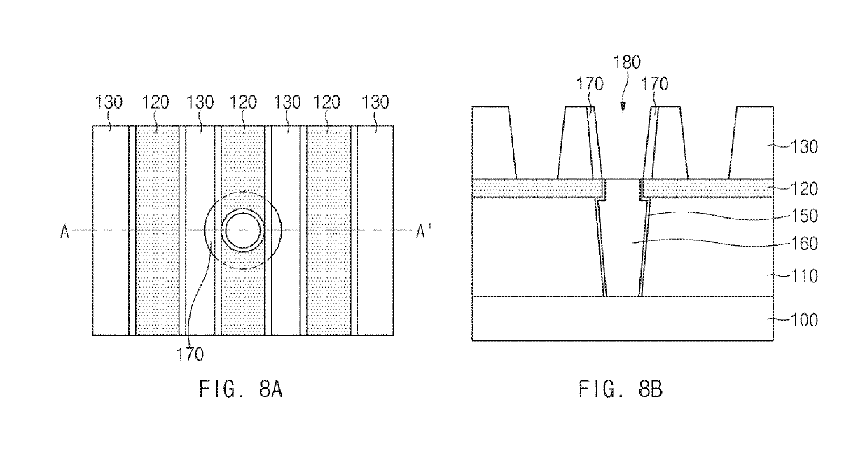

Referring to FIGS. 8A and 8B, the second interlayer insulation film 130 and the photoresist film 170 are etched using the photoresist pattern 170′ as the etch mask until the contact 160 is exposed, such that a trench 180 for defining a line-shaped metal line region is formed.

In this case, a lateral surface of the trench 180 may be tapered in a manner that the width of a lower part of the trench 180 is smaller than the width of an upper part of the trench 180.

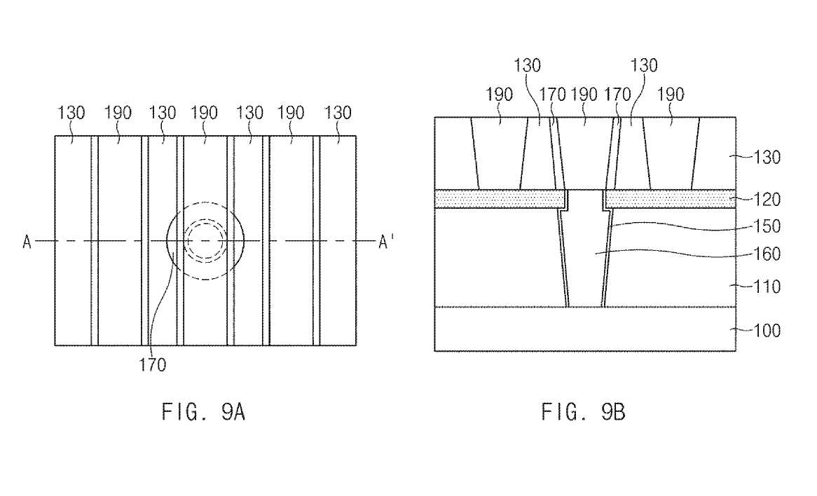

Referring to FIGS. 9A and 9B, after a conductive film is formed to bury the trench 180, the conductive film is planarized (e.g., CMP-processed), resulting in formation of a metal line 190. In this case, the metal line 190 may be a bit line, and the conductive film for the metal line 190 may include metal, for example, copper (Cu).

As is apparent from the above description, the semiconductor device and the method for manufacturing the same according to the embodiments can guarantee an overlay margin between a contact and a metal line.

Those skilled in the art will appreciate that embodiments of the present disclosure may be carried out in other ways than those set forth herein without departing from the spirit and essential characteristics of these embodiments. The above embodiments are therefore to be construed in all aspects as illustrative and not restrictive.

The above embodiments of the present disclosure are illustrative and not limitative. Various alternatives and equivalents are possible. The above embodiments are not limited by the type of deposition, etching polishing, and patterning steps described herein. Nor is the embodiment limited to any specific type of semiconductor device. For example, the present disclosure may be implemented in a dynamic random access memory (DRAM) device or a non-volatile memory device. Other additions, subtractions, or modifications are obvious in view of the present disclosure and are intended to fall within the scope of the appended claims.

What is claimed is:

1. A method for manufacturing a semiconductor device comprising:
forming a stacked insulation film in which a first interlayer insulation film, an etch stop film, and a second interlayer insulation film are sequentially stacked, over a lower structure;
forming a contact hole by etching the stacked insulation film;
forming a contact by burying a conductive film in the first interlayer insulation film and the etch stop film within the contact hole; and
forming a metal line coupled to a top surface of the contact.

2. The method according to claim 1, wherein the forming the stacked insulation film includes:
forming the first interlayer insulation film having a first etch selection ratio over the lower structure;
forming the etch stop film having a second etch selection ratio over the first interlayer insulation film; and
forming the second interlayer insulation film having the first etch selection ratio over the etch stop film.

3. The method according to claim 1, wherein the forming the stacked insulation film includes:
sequentially stacking an oxide film, a nitride film, and an oxide film.

4. The method according to claim 1, wherein the forming the contact hole includes:
etching the stacked insulation film in a manner that a width of the contact hole is gradually reduced in proportion to a depth of the contact hole and some parts of the etch stop film protrude inward from the contact hole.

5. The method according to claim 4, wherein the forming the contact includes:
forming a barrier metal film at an inner sidewall of the contact hole;
selectively etching a partial barrier metal film formed not only at a sidewall of the second interlayer insulation film but also over the etch stop film from among the barrier metal film;
forming a conductive film to bury the contact hole; and
selectively etching the conductive film formed in a region in which the barrier metal film is not formed.

6. The method according to claim 1, wherein the etch stop film is etched in a manner that a diameter formed by the protruded etch stop film is identical in size to a diameter of a bottom surface of the contact hole.

7. The method according to claim 1, wherein the forming the metal line includes:
forming a photoresist pattern defining a metal line region over the second interlayer insulation film;
forming a trench defining the metal line region by etching the second interlayer insulation film using the photoresist pattern as an etch mask until the contact is exposed; and
forming a conductive film to bury the trench.

8. The method according to claim 7, wherein the forming the trench includes:
obliquely forming a lateral surface of the trench in a manner that a width of a lower part of the trench is smaller than a width of an upper part of the trench.

9. The method according to claim 8, wherein the forming the trench includes:
forming the trench in a manner that the width of the lower part of the trench is identical to the width of the top surface of the contact.

10. A semiconductor device comprising:
a stacked insulation film in which a first interlayer insulation film, an etch stop film, and a second interlayer insulation film are sequentially stacked, over a lower structure;
a contact having an upper part buried in the etch stop film and a lower part buried in the first interlayer insulation film; and
a metal line formed to proceed in a first direction while simultaneously contacting a top surface of the contact, and formed to be buried in the second interlayer insulation film,
wherein a width of the lower part of the contact is gradually reduced in proportion to a depth within the first interlayer insulation film, and a width of the upper part of the contact is smaller than a width of a top surface of the lower part of the contact which is formed in the first interlayer insulation film.

11. The semiconductor device according to claim 10, further comprising:
a barrier metal film formed at a sidewall of the contact.

12. The semiconductor device according to claim 10, wherein:
a lateral surface of the metal line is tapered with a width of a bottom surface of the metal line being smaller than a width of a top surface of the metal line.

13. The semiconductor device according to claim 12, wherein the width of the bottom surface of the metal line is substantially identical to the width of the top surface of the contact.

14. The semiconductor device according to claim 10, wherein:
the width of the upper part of the contact which is formed in the etch stop film is substantially identical to the width of a bottom surface of the lower part of the contact which is formed in the first interlayer insulation layer.

15. The semiconductor device according to claim 10, wherein the first interlayer insulation film includes an oxide film.

16. The semiconductor device according to claim 15, wherein the etch stop film includes a nitride film.

17. The semiconductor device according to claim 16, wherein the second interlayer insulation film includes an oxide film.

18. The semiconductor device according to claim 10, wherein the contact includes tungsten (W).

19. The semiconductor device according to claim 10, wherein the metal line includes copper (Cu).
